(19) United States
(12) Patent Application Publication
(10) Pub. No.: US 2014/0061887 A1
(43) Pub. Date: Mar. 6, 2014

(54) SEMICONDUCTOR DEVICE AND MANUFACTURING METHOD OF SEMICONDUCTOR DEVICE

(71) Applicant: Fujitsu Semiconductor Limited, Yokohama-shi (JP)

(72) Inventors: Hayato OKUDA, Kawasaki (JP); Yoshikazu KUMAGAYA, Sagamihara (JP)

(73) Assignee: Fujitsu Semiconductor Limited, Yokohama-shi (JP)

(21) Appl. No.: 13/971,314

(22) Filed: Aug. 20, 2013

(30) Foreign Application Priority Data
Sep. 4, 2012 (JP) 2012-194358

(51) Int. Cl. H01L 23/10; H01L 21/56

(52) U.S. Cl. CPC H01L 23/10; H01L 21/56
USPC 257/686; 438/109

(57) ABSTRACT

A semiconductor device includes: a plurality of semiconductor chips to be mutually bonded via a bonding resin; a sealing resin to seal the plurality of semiconductor chips; and an anchor to be disposed in a first semiconductor chip included by the plurality of semiconductor chips and to seize the bonding resin.

### CROSS-REFERENCE TO RELATED APPLICATION

This application is based upon and claims the benefit of priority of the prior Japanese Patent Application No. 2012-194358, filed on Sep. 4, 2012, the entire contents of which are incorporated herein by reference.

### FIELD

The present application discloses a semiconductor device and a manufacturing method of the semiconductor device.

### BACKGROUND

Some of the semiconductor devices are contrived to improve an adhesive property between a semiconductor chip and a sealing resin for sealing the semiconductor chip (refer to, e.g., Patent document 1).

### PATENT DOCUMENT

[Patent document 1] Japanese Patent Application Laid-Open Publication No. 2005-317860

### SUMMARY

The present application discloses a semiconductor device that is given as below.

A semiconductor device comprising:

a plurality of semiconductor chips to be mutually bonded via a bonding resin;

a sealing resin to seal the plurality of semiconductor chips; and

an anchor to be disposed in a first semiconductor chip included by the plurality of semiconductor chips and to seize the bonding resin.

Further, the present application discloses a manufacturing method of the semiconductor device, which is given as follows.

A manufacturing method of a semiconductor device, comprising:

a step of bonding a plurality of semiconductor chips mutually via a bonding resin;

a step of sealing the plurality of semiconductor chips by a sealing resin; and

a step of disposing an anchor to seize the bonding resin in a first semiconductor chip included by the plurality of semiconductor chips.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view illustrating a structure of a semiconductor device according to an embodiment;

FIG. 2 is a sectional view of the semiconductor device, illustrating a part of the section taken along the line A-A in FIG. 1;

FIG. 3 is a diagram illustrating, as an image, one example of a mechanism of how a malfunction occurs in a heat cycle test of the semiconductor device;

FIG. 4 is a top view of a test object simulating the semiconductor device having a stack structure in which the plurality of semiconductor chips is stacked;

FIG. 5 is a side view of the side, depicted as a “side C” in FIG. 4, of the test object;

FIG. 6 is a side view of the side, depicted as a “side D” in FIG. 4, of the test object;

FIG. 7 is a first view illustrating a flow of assembling steps of the test object;

FIG. 8 is a second view illustrating the flow of assembling steps of the test object;

FIG. 9 is a third view illustrating the flow of assembling steps of the test object;

FIG. 10 is a view illustrating a retracted state of a bonding resin of the test object;

FIG. 11 is a view representing a relation between a density of the wire and the retraction of the bonding resin;

FIG. 12 is a view illustrating a step of fitting the semiconductor chip to a substrate;

FIG. 13 is a view illustrating a step of applying wire bonding to a lower semiconductor chip;

FIG. 14 is a view illustrating a step of preparing an upper semiconductor chip;

FIG. 15 is a view illustrating a step of bonding the upper semiconductor chip to the lower semiconductor chip;

FIG. 16 is a view illustrating a step of separating a collet from the upper semiconductor chip;

FIG. 17 is a view illustrating a step of applying the wire bonding to the upper semiconductor chip;

FIG. 18 is a view illustrating a step of sealing the semiconductor chips by a sealing resin;

FIG. 19 is a structural view illustrating a part of a semiconductor device according to a first modified example;

FIG. 20 is a structural view illustrating a part of the semiconductor device according to a second modified example;

FIG. 21 is a view illustrating a flow of manufacturing a projection according to a first example;

FIG. 22A is a view illustrating a step of coating an insulating film;

FIG. 22B is a view illustrating a step of etching the insulating film 21;

FIG. 22C is a view illustrating a step of forming a base metal film;

FIG. 22D is a view illustrating a step of coating a resist;

FIG. 22E is a view illustrating a step of etching the resist 23;

FIG. 22F is a view illustrating a step of forming the pillar;

FIG. 22G is a view illustrating a step of removing the resist 23;

FIG. 22H is a view illustrating a step of etching the base metal film 22;

FIG. 22I is a view illustrating a step of reflowing the solder 25;

FIG. 23A is first view illustrating a flow of manufacturing the projection 6 according to the third example;

FIG. 23B is second view illustrating a flow of manufacturing the projection 6 according to the third example;

FIG. 23C is third view illustrating a flow of manufacturing the projection 6 according to the third example;

FIG. 23D is a view illustrating a step of coating the resist;

FIG. 23E is a view illustrating a step of etching the resist 33;

FIG. 23F is a view illustrating a step of forming a solder bump;

FIG. 23G is a view illustrating a step of removing the resist 33;

FIG. 23H is a view illustrating a step of etching the base metal film 32; and

FIG. 23I is a view illustrating a step of reflowing the solder bump.

### DESCRIPTION OF EMBODIMENTS

An embodiment of the present disclosure will hereinafter be described. The embodiment, which will be demonstrated as below, is an exemplification of one mode of the present disclosure, but it does not mean that the technical scope of the present disclosure is limited to the following mode.

### EMBODIMENT OF SEMICONDUCTOR DEVICE

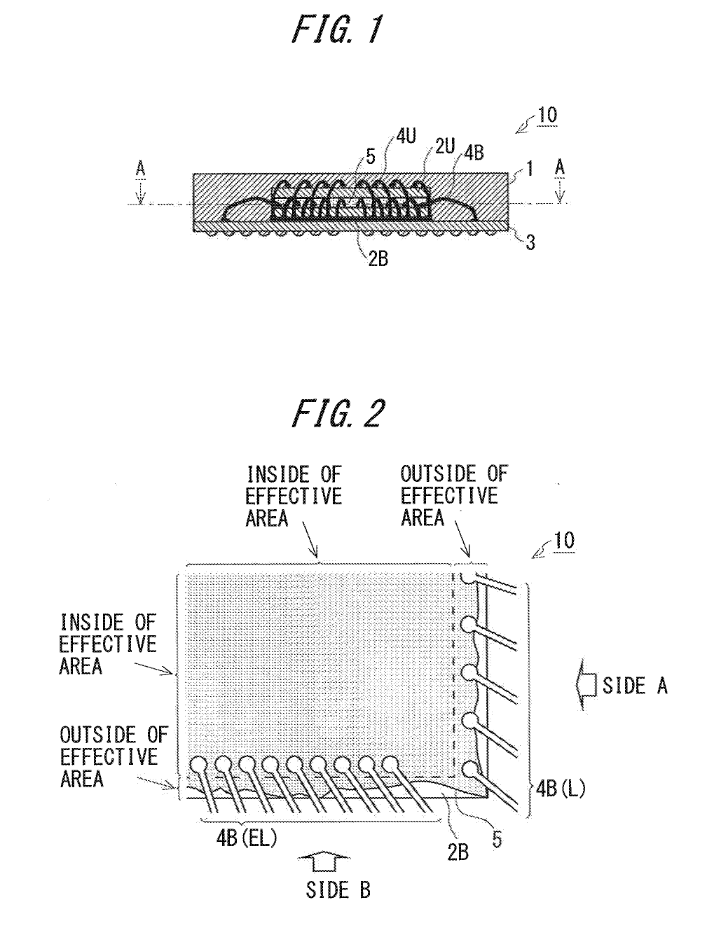

FIG. 1 is a view illustrating a structure of the semiconductor device according to the embodiment. A semiconductor device 10 according to the embodiment is a semiconductor device having a stack structure in which a plurality of semiconductor chips is stacked, and includes two pieces of semiconductor chips 2U, 2B sealed by a sealing resin 1. Note that the discussion on the embodiment and a modified example demonstrated as below proceeds by taking the semiconductor device including the two semiconductor chips for example, however, three or more semiconductor chips are also available.

In the two semiconductor chips 2U, 2B, the semiconductor chip 2B (which is one example of “a first semiconductor chip” according to the present application) disposed on a lower side is fixed onto a substrate 3 (e.g., an interposer etc.). Further, the semiconductor chip 2B and the substrate 3 are connected to each other via a wire 4B. Still further, the semiconductor chip 2U is fixed to the semiconductor chip 2B and is electrically connected to the substrate 3 via a wire 4U.

Note that the wire 4B includes not only a wire element taking a role of electrically connecting the semiconductor chip 2B and the substrate 3 together but also a wire element taking a role of seizing a bonding resin 5 for fixing the semiconductor chip 2U to the semiconductor chip 2B as will be described later on. This being the case, in the following discussion, the wire element 4B, of the wire 4B, taking the role of electrically connecting the semiconductor chip 2B and the substrate 3 together is called a wire 4B(E). Further, the wire element 4B, of the wire 4B, taking the role of seizing the bonding resin 5 is called a dummy wire 4B(L) (which is one example of an “anchor” according to the present application). It is to be noted that the wire 4B(E) taking the role of electrically connecting the semiconductor chip 2B and the substrate 3 together can include a wire element concurrently having the role of seizing the bonding resin 5. This being the case, the wire (wire element) 4B(E), which concurrently has the role of seizing the bonding resin 5, is especially called a wire 4B(EL). The wire 4B(EL) is not, however, embraced by the “anchor” according to the present application.

The bonding resin 5 for fixing the semiconductor chip 2U having a size just equal to or equal to or larger than a size of the semiconductor chip 2B to the semiconductor chip 2B, involves using a wire-embedded DAF (Die Attach Film) excellent in terms of simplifying a manufacturing process of the semiconductor device 10 and downsizing the device. Hence, a part of the wire 4B connected to the semiconductor chip 2B comes to a state of being embedded in the bonding resin 5.

FIG. 2 is a sectional view of the semiconductor device 10, illustrating a part of the section taken along the line A-A in FIG. 1. The semiconductor chip 2B is fitted with, in addition to the wire 4B(EL) that electrically connects the semiconductor chip 2B and the substrate 3 together, the dummy wire 4B(L) for seizing the bonding resin 5. The dummy wire 4B(L) is provided on the side depicted as a “side A” in FIG. 2 with respect to the semiconductor chip 2B. Further, the wire 4B(EL) is provided on the side depicted as a “side B” in FIG. 2 with respect to the semiconductor chip 2B.

Note that the wire 4B(EL) controls the role of electrically connecting the semiconductor chip 2B and the substrate 3 together and is therefore, as illustrated in FIG. 2, bonded within an effective area of the semiconductor chip 2B. While on the other hand, the dummy wire 4B(L) does not control the role of electrically connecting the semiconductor chip 2B and the substrate 3 together and can be therefore, if being edges of the semiconductor chip 2B, bonded to anywhere inside and outside the effective area of the semiconductor chip 2B. Namely, as illustrated in FIG. 2, the dummy wire 4B(L), if the edge of the bonding resin 5 can be seized to somewhere outside the effective area, may be bonded to somewhere outside the effective area and may also be alternatively bonded to a portion inside the effective area.

A bonding position of the dummy wire 4B(L) taking the role of seizing the bonding resin 5 is determined based on the following point of view.

The bonding resin 5, into which some portion of the wire 4B is embedded, is required to fill a periphery of the wire 4B without deforming the wire 4B when die-bonding. Further, the sealing resin 1 is required to protect the semiconductor chip 2U and the semiconductor chip 2B from outside. Hence, a coefficient of linear expansion of the bonding resin 5 is different from a coefficient of linear expansion of the sealing resin 1 as the case may be, depending on a difference between a material used for the bonding resin 5 and a material used for the sealing resin 1. If the coefficient of linear expansion of the bonding resin 5 is different from the coefficient of linear expansion of the sealing resin 1, an interface between the bonding resin 5 and the sealing resin 1 moves as a temperature of the semiconductor device 10 changes.

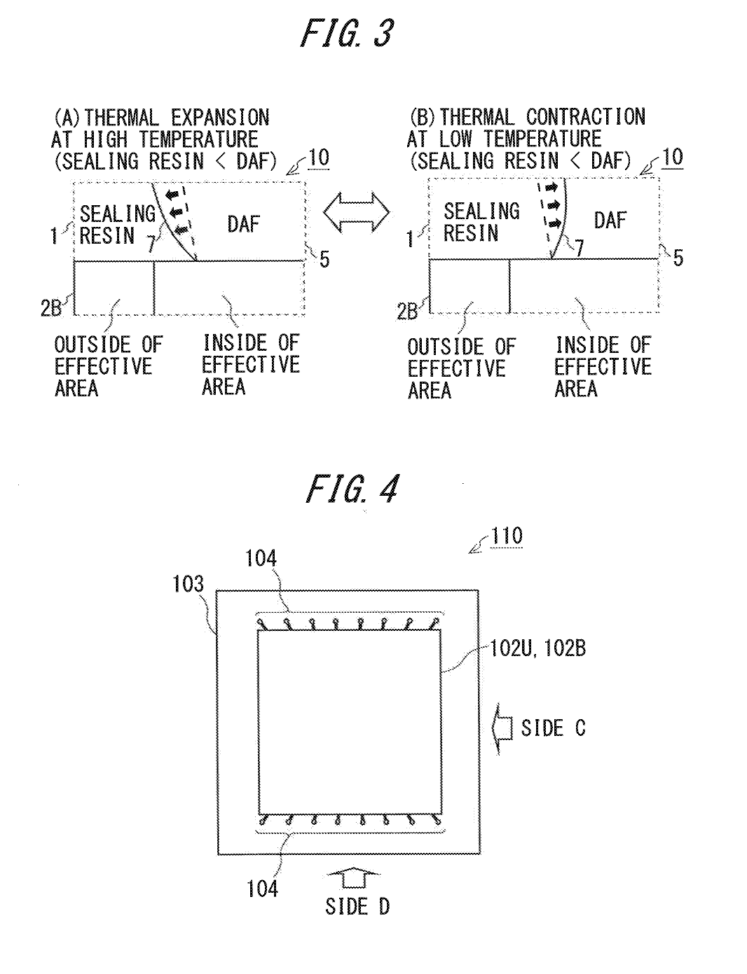

FIG. 3 is a diagram illustrating, as an image, one example of a mechanism of how a malfunction occurs in a heat cycle test of the semiconductor device 10. For example, if the coefficient of linear expansion of the bonding resin 5 is larger than the coefficient of linear expansion of the sealing resin 1, an interface 7 between the bonding resin 5 and the sealing resin 1 moves toward the sealing resin 1 as the temperature of the semiconductor device 10 rises and moves toward the bonding resin 5 as the temperature of the semiconductor device 10 falls. A portion, abutting on the semiconductor chip 2B, of the interface 7 between the bonding resin 5 and the sealing resin 1, is bonded to the semiconductor chip 2B but does not therefore move on the surface of the semiconductor chip 2B. As a result, it follows that a stress is applied to an electronic circuit on the surface of the semiconductor chip 2B through repetitions of expansions and contractions due to the heat cycles. It is therefore desired that the interface 7 between the bonding resin 5 and the sealing resin 1 is formed at least outside the effective area on the surface of the semiconductor chip 2B.

By the way, the interface 7 between the bonding resin 5 and the sealing resin 1 is formed through permeation of the sealing resin 1 in between the semiconductor chip 2U and the semiconductor chip 2B that are bonded by the bonding resin 5. Hence, the position of forming the interface 7 is determined based on the position of the bonding resin 5 when sealed by the sealing resin 1. Accordingly, if the bonding resin 5 gets deformed before being sealed by the sealing resin 1, it follows that the interface 7 is formed in an unintended area on the surface of the semiconductor chip 2B.

The deformation of the bonding resin 5 occurs due to, e.g., the following mechanism. FIG. 4 is a top view of a test object simulating the semiconductor device having the stack structure in which the plurality of semiconductor chips is stacked. A test object 110 is not provided with a wire on the side depicted as a “side C” in FIG. 4 in a simulation chip 102B simulating the semiconductor chip 2B but is provided with a wire 104 on the side depicted as a “side D” in FIG. 4.

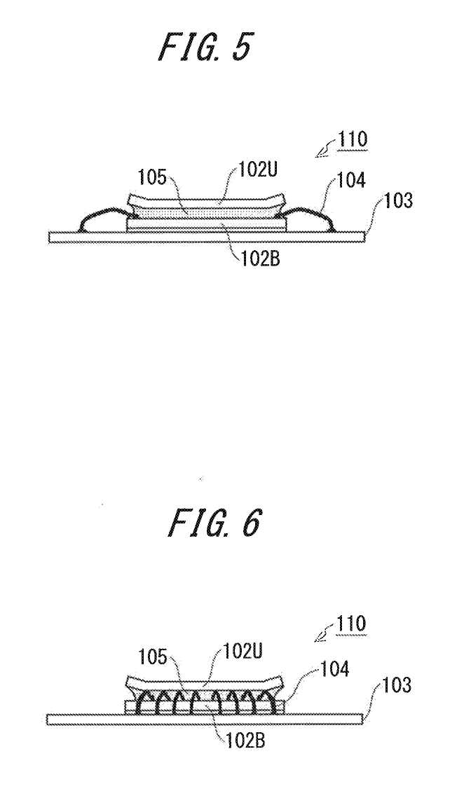

FIG. 5 is a side view of the side, depicted as the “side C” in FIG. 4, of the test object 110. Furthermore, FIG. 6 is a side view of the side, depicted as the “side D” in FIG. 4, of the test object 110. The wire 104 connects, similarly to the wire 4B of the semiconductor device 10, the simulation chip 102B simulating the semiconductor chip 2B and the substrate 3 to each other. Moreover, a part of the wire 104 is, similarly to the semiconductor device 10, embedded in a bonding resin 105 that bonds a simulation chip 102U simulating the semiconductor chip 2U and the simulation chip 102B to each other.

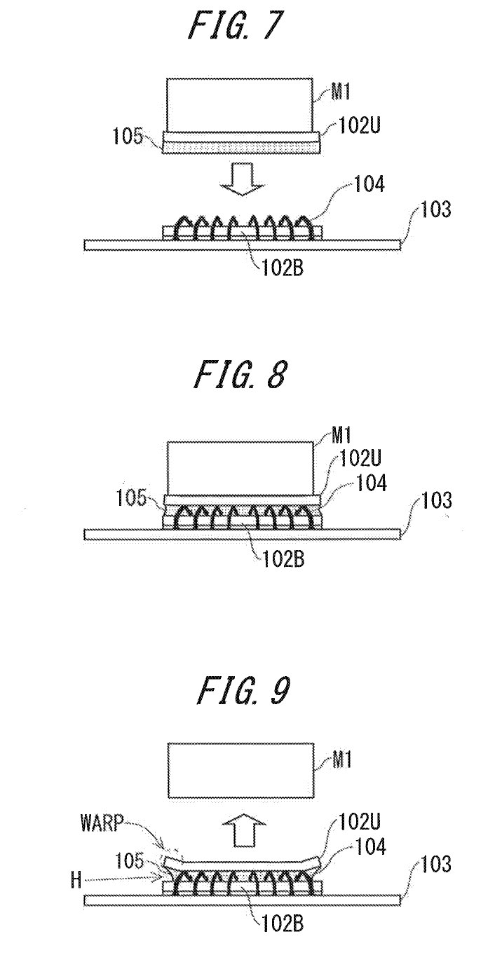

FIGS. 7-9 are views illustrating a flow of assembling steps of the test object 110. When assembling the test object 110, the simulation chip 102U is prepared in such a way that the chip 102U is, after being diced, held by a collet Ml, and the bonding resin 5 is adhered to the lower surface thereof (FIG. 7). Next, the simulation chip 102U adhered with the bonding resin 5 is bonded to the simulation chip 102B (FIG. 8). Subsequently, the collet M1 is separated from the simulation chip 102U by cancelling vacuum adsorption of the collet M1 (FIG. 9). Herein, for instance, if a warp of the simulation chip 102U appears after die-bonding for the reason that the simulation chip 102U is thin in thickness etc., the soft bonding resin 105 becomes a state of retracting, as indicated by the symbol “H” in FIG. 9, toward the central portion of the simulation chip 102U by a volumetric quantity of floating due to the warp of the simulation chip 102U.

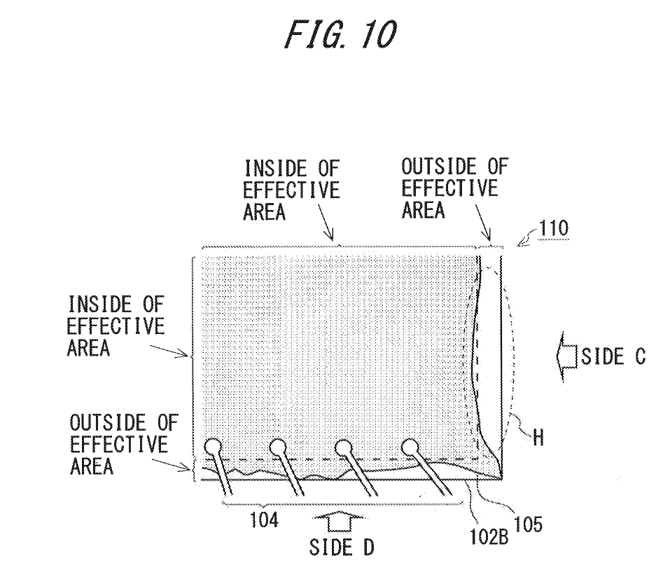

FIG. 10 is a view illustrating the retracted state of the bonding resin 105 of the test object 110. The wire 104 is embedded in the bonding resin 105 on the side of the “side D” on which the wire 104 is bonded. Hence, the bonding resin 105, on the side of the “side D” to which the wire 104 is bonded, is seized by the surface of the simulation chip 102B by dint of an anchor effect of the wire 104. On the other hand, the wire 104 is not embedded in the bonding resin 105 on the side of the “side C” to which the wire 104 is not bonded. Therefore, the anchor effect of the wire 104 does not work on the bonding resin 105 on the side of the “side C” to which the wire 104 is not bonded. As a result, the retraction of the bonding resin 105 gets, as indicated by the symbol “H” in FIG. 10, more distinguished on the side of the “side C” to which the wire 104 is not bonded than on the side of the “side D” to which the wire 104 is bonded. If the bonding resin 105 is remarkably retracted, the interface between the bonding resin 105 and the sealing resin comes to have a high possibility of being formed in the unintended area on the surface of the simulation chip 102B. For example, in FIG. 10, as depicted on the side of the “side C” in FIG. 10, if the retraction of the bonding resin 105 extends into the effective area, it follows that the interface between the bonding resin 105 and the sealing resin is formed in the effective area defined as the unintended area.

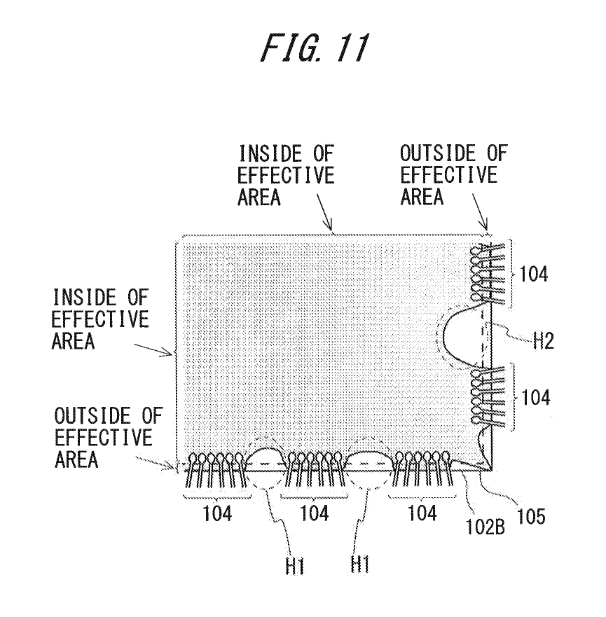

Note that the retraction of the bonding resin 105 does not depend on only whether the wire 104 exists or not. FIG. 11 is a view representing a relation between a density of the wire 104 and the retraction of the bonding resin 105. For example, the small retraction of the bonding resin 105 is seen as indicated by the symbol H1 in FIG. 11 at the portion with a large bonding quantity of the wire 104. While on the other hand, the large retraction of the bonding resin 105 is seen as indicated by the symbol H2 in FIG. 11 at the portion with a small bonding quantity of the wire 104. If the retraction of the bonding resin 105 is large, it follows that the interface between the bonding resin 105 and the sealing resin is formed in a state of largely permeating into the effective area defined as the unintended area.

Such being the case, in the semiconductor device 10 according to the embodiment, the bonding position of the dummy wire 4B(L) is determined so that the interface 7 between the bonding resin 5 and the sealing resin 1 is formed outside the effective area on the surface of the semiconductor chip 2B. To be specific, in the semiconductor device 10 according to the embodiment, with the bonding resin 5 being retracted, the dummy wire 4B(L) is laid out at such a portion that the interface 7 is formed inside the effective area on the surface of the semiconductor chip 2B. Note that the wire element of the wire 4B(E) arranged for the electric connection is, due to the retraction of the bonding resin 105, arranged at the portion where the interface 7 is formed inside the effective area on the surface of the semiconductor chip 2B, and becomes the wire 4B(EL) because of concurrently taking the role of seizing the bonding resin 5. In this case, the wire 4B(EL) controls the role of assisting the function, incorporated into the dummy wire 4B(L), of seizing the bonding resin 5.

For instance, an assumption is that in the semiconductor chip 2B according to the embodiment, none of the portion requiring the electric connection is provided on the side depicted as the “side A” in FIG. 2. On the other hand, another assumption is that in the semiconductor chip 2B, the portion requiring the electric connection is provided on the side depicted as the “side B” in FIG. 2. In this case, if the wire 4B does not exist on the side as depicted as the “side A” in the semiconductor chip 2B, it follows that the bonding resin 5 is conspicuously retracted. Such being the case, in the semiconductor device 10 according to the embodiment, the dummy wire 4B(L) is fitted to the portion (e.g., the edge of the semiconductor chip 2B) that does not require the electric connection in the semiconductor chip 2B, thus reducing the possibility that the interface 7 is formed inside the effective area on the surface of the semiconductor chip 2B.

Note that the dummy wire 4B(L) is fitted to the side different from the side to which the wire 4B(EL) is fitted in FIG. 2. The dummy wire 4B(L) may, however, be fitted to the same side as the side to which the wire 4B(EL) is fitted. In this case, the dummy wire 4B(L) may be fitted adjacent to the wire 4B(EL) and may also be fitted to between the wire 4B(EL) and the wire 4B(EL).

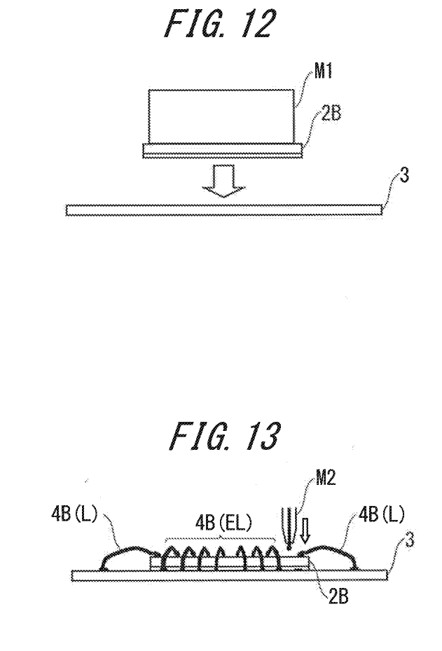

A method of manufacturing the semiconductor device 10 will hereinafter be described based on a flow of the assembling steps of the semiconductor device 10 illustrated in FIGS. 12 through 19.

FIG. 12 is a view illustrating the step of fitting the semiconductor chip 2B to the substrate 3. When assembling the semiconductor device 10, the diced semiconductor chip 2B is held by the collet M1 through the vacuum adsorption and is bonded onto the substrate 3.

FIG. 13 is a view illustrating the step of applying the wire bonding to the semiconductor chip 2B provided on the underside. After fitting the semiconductor chip 2B to the substrate 3, the wire 4B(EL) and the dummy wire 4B(L) are bonded to between the semiconductor chip 2B and the substrate 3 by use of a bonder M2.

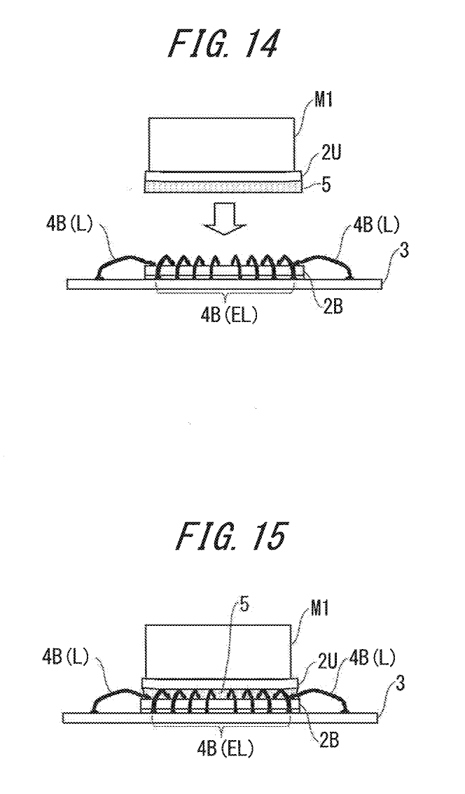

FIG. 14 is a view illustrating the step of preparing the semiconductor chip 2U. After applying the wire bonding to the semiconductor chip 2B, the semiconductor chip 2U is prepared in such a manner that the semiconductor chip 2U is held by the collet M1, and the bonding resin 5 is adhered to the undersurface thereof.

FIG. 15 is a view illustrating the step of bonding the upper semiconductor chip 2U to the lower semiconductor chip 2B. After preparing the semiconductor chip 2U with the bonding resin 5 being adhered to the undersurface thereof, this semiconductor chip 2U is bonded to the semiconductor chip 2B.

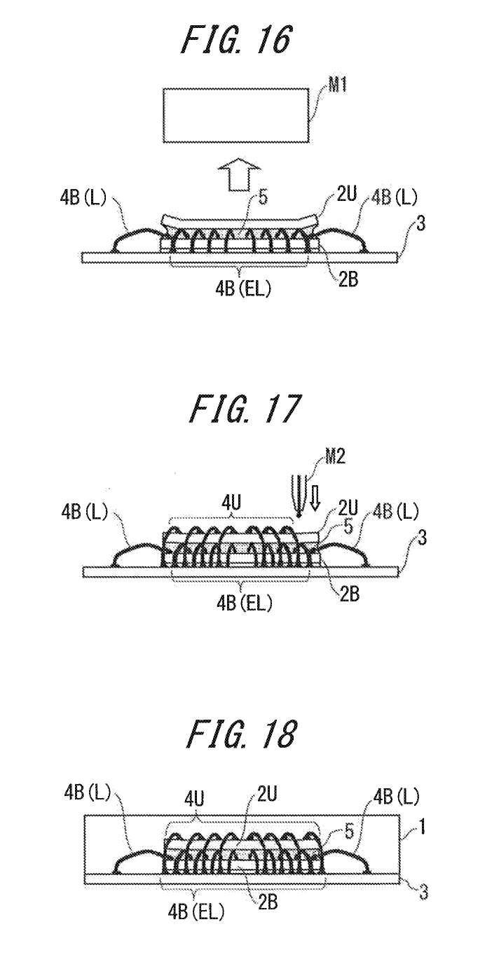

FIG. 16 is a view illustrating the step of separating the collet M1 from the semiconductor chip 2U. After bonding the semiconductor chip 2U to the semiconductor chip 2B, the collet M1 is separated from the semiconductor chip 2U by canceling the vacuum adsorption of the collet M1.

FIG. 17 is a view illustrating the step of applying the wire bonding to the upper semiconductor chip 2U. After separating the collet M1 from the semiconductor chip 2U, the wire 4U is bonded to between the semiconductor chip 2U and the substrate 3 by use of the bonder M2.

FIG. 18 is a view illustrating the step of sealing the semiconductor chips 2U, 2B by the sealing resin 1. After bonding the wire 4U to between the semiconductor chip 2U and the substrate 3, the semiconductor chips 2U, 2B are sealed by the sealing resin 1.

The manufacturing method of the semiconductor device 10 is as described above. According to the manufacturing method of the semiconductor device 10, not only the wire 4B(EL) but also the dummy wire 4B(L) is bonded to the semiconductor chip 2B. Hence, even when the semiconductor chips 2U, 2B are sealed by the sealing resin 1, such a possibility decreases that the interface 7 is formed in the unintended position on the surface of the semiconductor chip 2B. Therefore, the manufacturing method of the semiconductor device 10 enables the interface 7 to be formed outside the effective area on the surface of the semiconductor chip 2B. If the interface 7 is formed at east outside the effective area on the surface of the semiconductor chip 2B, even with the repetitions of the expansions and the contractions of the semiconductor device 10 due to the heat cycles, there are reduced the stresses applied to the electronic circuits such as the wires etc. formed inside the effective area on the surface of the semiconductor chip 2B. Consequently, the semiconductor device 10 has more improved capability against the heat cycles than the semiconductor devices according to the examples of the prior arts.

### FIRST MODIFIED EXAMPLE

It should be noted that the wire 4B(E) of the semiconductor device 10 is the wire 4B(EL) concurrently having the role of seizing the bonding resin 5. The wire 4B(E) of the semiconductor device 10 is not, however, limited to the wire 4B(EL) concurrently having the role of seizing the bonding resin 5.

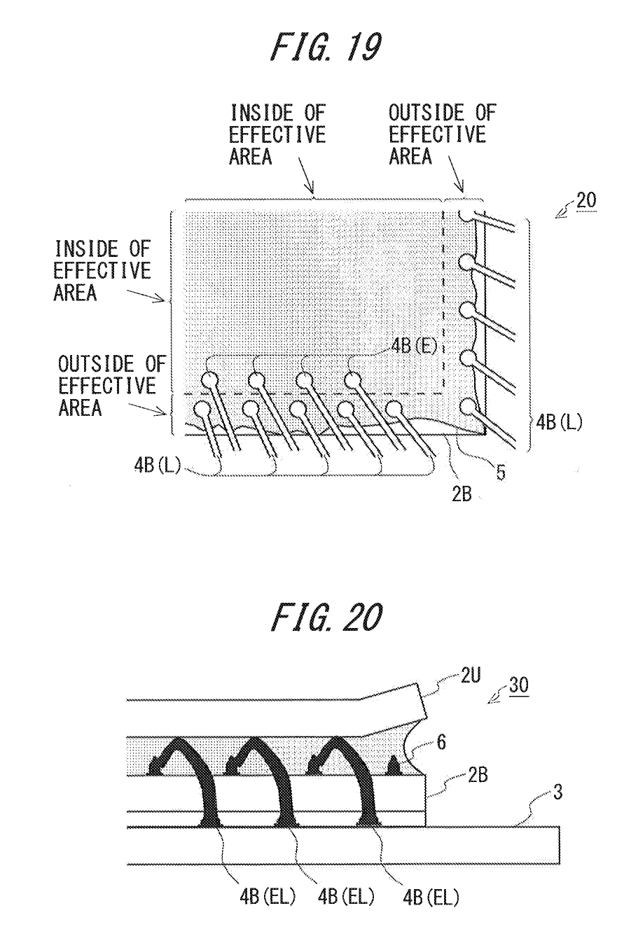

FIG. 19 is a structural view illustrating a part of a semiconductor device 20 according to a first modified example. In the semiconductor device 20 according to the first modified example, the wire 4B(E) is bonded to each of electrode pads existing at the portion spaced away from the edge of the semiconductor chip 2B in the electrode pads formed on the surface of the semiconductor chip 2B disposed on the lower side. The wire 4B(E) is bonded to the electrode pad at the portion spaced away from the semiconductor chip 2B and is therefore disabled from taking the role of seizing the bonding resin 5. Such being the case, in the semiconductor device 20 according to the first modified example, the dummy wire 4B(L) taking the role of seizing the bonding resin 5 is bonded to a chip edge existing farther outside than the portion to which the wire 4B(E) is bonded.

Thus, if the wire 4B(E) taking the role of electrically connecting the semiconductor chip 2B and the substrate 3 together cannot currently have the role of seizing the bonding resin 5, the dummy wire 4B(L) taking the role of seizing the bonding resin 5 is provided, thereby enabling the reduction of the possibility that the interface 7 is formed in the unintended position on the surface of the semiconductor chip 2B.

### SECOND MODIFIED EXAMPLE

By the way, in the semiconductor device 10 according the embodiment discussed above and the semiconductor device 20 according to the first modified example, the dummy wire 4B(L) is bonded to between the semiconductor chip 2B and the substrate 3. The dummy wire 4B(L) does not, however, take the role of establishing the electric connection between the semiconductor chip 2B and the substrate 3. Namely, if what is enabled to take the role of seizing the bonding resin 5 is provided at the portion to which the dummy wire 4B(L) is bonded, some sort of element other than the wire 4B may also be provided. Such being the case, the semiconductor device according the embodiment discussed above and the semiconductor device 20 according to the first modified example may be modified as follows.

FIG. 20 is a structural view illustrating a part of a semiconductor device 30 according to a second modified example. The semiconductor device 30 according to the second modified example includes a projection 6 (which is one example of the “anchor” according to the present application) taking the role of seizing the bonding resin 5 in place of the dummy wire 4B(L). A fitting position of the projection 6 is coincident with the position where the dummy wire 4B(L) is bonded. When the semiconductor chip 2U adhered with the bonding resin 5 is bonded to the semiconductor chip 2B, the projection 6 comes to a state of being embedded in the bonding resin 5. Hence, even in the case of providing the projection in place of the dummy wire 4B(L), similarly to the semiconductor device 10 according the embodiment discussed above and the semiconductor device 20 according to the first modified example, it is feasible to reduce the possibility that the interface 7 is formed in the unintended position on the surface of the semiconductor chip 2B. Incidentally, the projection 6 can be manufactured, e.g., in the following way.

### FIRST EXAMPLE OF PROJECTION MANUFACTURING METHOD

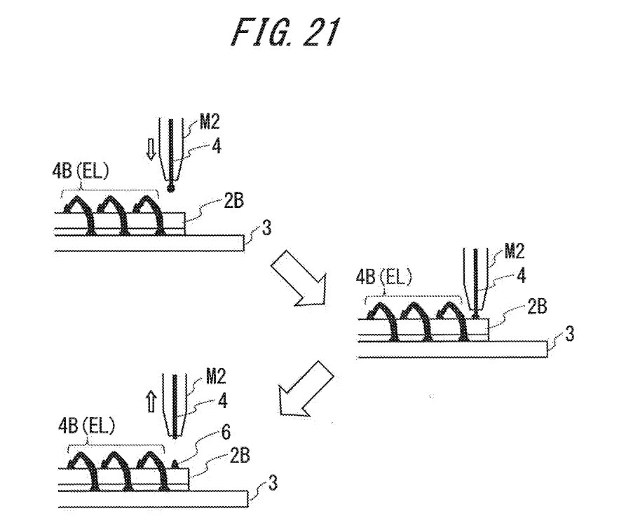

FIG. 21 is a view illustrating a first example of a method of manufacturing the projection 6. The projection 6 can be formed by modifying as below the step of forming the dummy wire 4B(L) by applying the wire bonding to the semiconductor chip 20B. Specifically, in the step of forming the dummy wire 4B(L), after a tip of the wire 4 worked in a ball shape has been bonded to the electrode pad of the semiconductor chip 20B, the bonder M2 is moved without feeding the wire 4 from the bonder M2. With this contrivance, the wire disconnected midway is fitted in a projected shape to the electrode pad of the semiconductor chip 20B, thus coming to a state of forming the projection 6.

### SECOND EXAMPLE OF PROJECTION MANUFACTURING METHOD

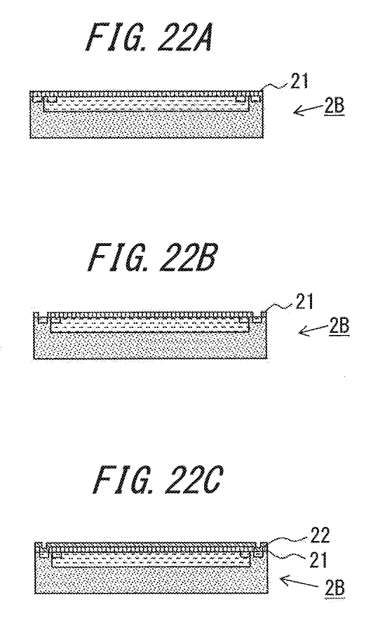

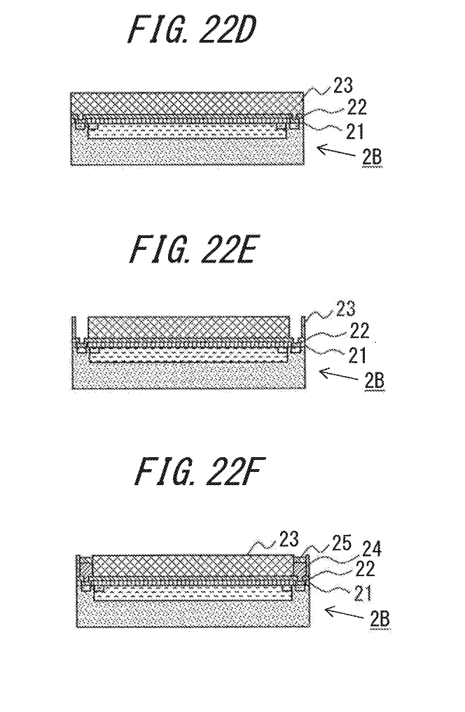

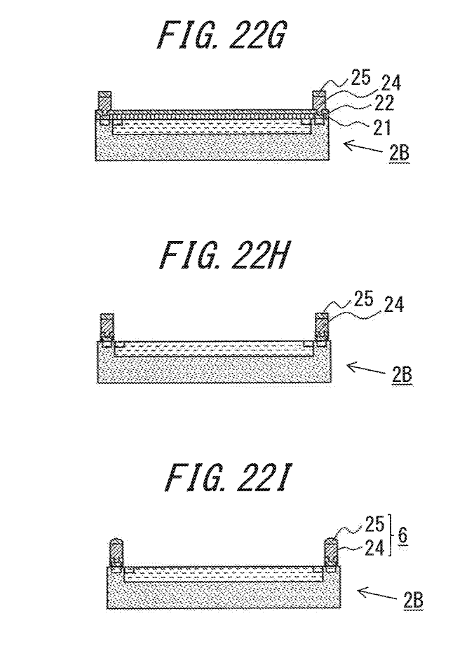

A second example of the method of manufacturing the projection 6 will hereinafter be described. FIG. 22 is a view illustrating a flow of manufacturing the projection 6 according to the second example.

FIG. 22(A) is a view illustrating a step of coating an insulating film. On the occasion of manufacturing the projection 6 on the surface of the semiconductor chip 2B, in a so-called “pre-step” before dicing the semiconductor chip 2B, an insulating film 21 is coated over the surface of the semiconductor chip 2B.

FIG. 22(B) is a view illustrating a step of etching the insulating film 21. After coating the insulating film over the surface of the semiconductor chip 2B, the insulating film 21 is etched in the way of being exposed to the light by masking regions other than the electrode pads not requiring the electric connections, which are provided for the projections.

FIG. 22(C) is a view illustrating a step of forming a base metal film. After etching the insulating film 21, metal sputtering is applied over the surface of the semiconductor chip 2B, thus forming a base metal film 22 on the surface of the semiconductor chip 2B.

FIG. 22(D) is a view illustrating a step of coating a resist. After forming the base metal film 22 on the surface of the semiconductor chip 2B, a resist 23 for pillar is coated over the surface of the semiconductor chip 2B.

FIG. 22(E) is a view illustrating a step of etching the resist 23. After coating the resist 23 over the surface of the semiconductor chip 2B, the resist 23 is etched in the way of being exposed to the light by masking regions other than the electrode pads formed with the projections 6.

FIG. 22(F) is a view illustrating a step of forming the pillar. After etching the resist 23, there are formed a Cu pillar 24 and a solder 25 on the surface of the pillar 24 by a plating method.

FIG. 22(G) is a view illustrating a step of removing the resist 23. After forming the Cu pillar 24 and the solder 25 on the surface thereof, the resist 23 is removed by etching.

FIG. 22(H) is a view illustrating a step of etching the base metal film 22. After removing the resist 23, the base metal film 22 and the insulating film 21, which are exposed due to the removal of the resist 23, are then removed by etching.

FIG. 22(I) is a view illustrating a step of reflowing the solder 25. After the base metal film 22 has been removed by etching, the semiconductor chip 20B is preheated, and the solder 25 is reflowed.

A second example of manufacturing the projection 6 is as described above. According to the method described above, the pillar-shaped projection 6 can be formed.

### THIRD EXAMPLE OF PROJECTION MANUFACTURING METHOD

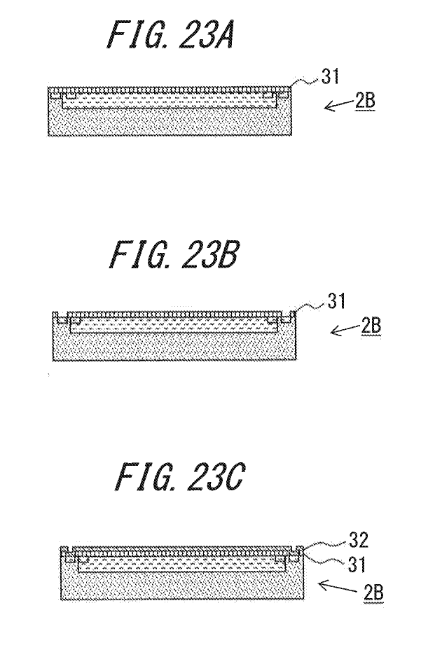

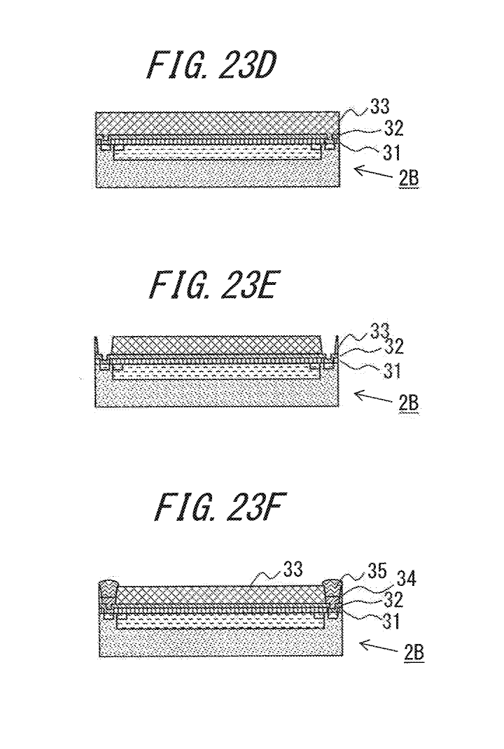

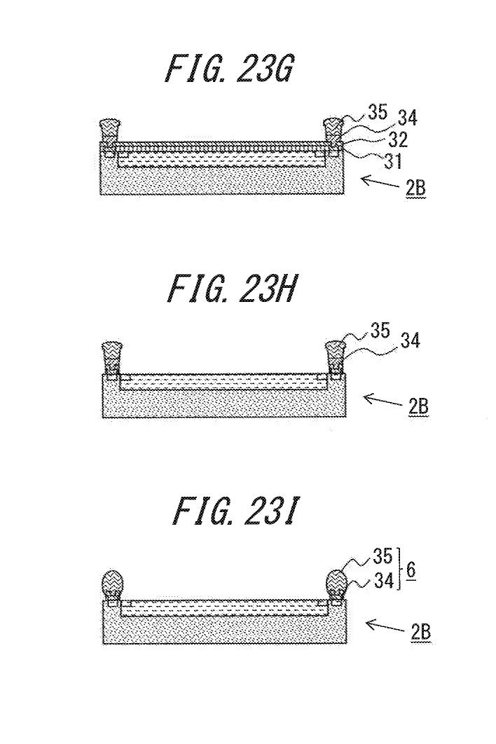

Note that in the second example of the projection manufacturing method, the pillar-shaped projection 6 is formed, however, the projection manufacturing method according to the second example maybe modified as below. The third example of the projection manufacturing method will hereinafter be described. FIG. 23 is a view illustrating a flow of manufacturing the projection 6 according to the third example.

A step of coating an insulating film 31 over the surface of the semiconductor chip 2B (see FIG. 23(A)), a step of etching the insulating film 31 (see FIG. 23(B)) and a step of forming a base metal film 32 (see FIG. 23(C)) are the same as those depicted in FIGS. 22(A)-22(C), and hence their explanations are omitted.

FIG. 23(D) is a view illustrating a step of coating the resist. After forming the base metal film 22 on the surface of the semiconductor chip 2B, a resist 33 for a bump is coated over the surface of the semiconductor chip 2B.

FIG. 23(E) is a view illustrating a step of etching the resist 33. After coating the resist 33 over the surface of the semiconductor chip 2B, the resist 33 is etched in the way of being exposed to the light by masking regions other than the electrode pads formed with the projections 6.

FIG. 23(F) is a view illustrating a step of forming a solder bump. After etching the resist 33, an under barrier metal (UBM) 34 and a solder bump 35 are formed by the plating method etc.

FIG. 23(G) is a view illustrating a step of removing the resist 33. After forming the UBM 34 and the solder bump 3, the resist 33 is removed by etching etc.

FIG. 23(H) is a view illustrating a step of etching the base metal film 32. After removing the resist 33, the base metal film 32 exposed by removing the resist 33 is then removed by etching.

FIG. 23(I) is a view illustrating a step of reflowing the solder bump. After removing the base metal film 32 by etching, the semiconductor chip 2B is pre-heated, and the solder bump 35 is reflowed.

The third example of the method of manufacturing the projection 6 is as described above. According to the method described above, the projection 6 taking the solder-bump shape can be formed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a plurality of semiconductor chips to be mutually bonded via a bonding resin;
a sealing resin to seal the plurality of semiconductor chips; and
an anchor to be disposed in a first semiconductor chip included by the plurality of semiconductor chips and to seize the bonding resin.

2. The semiconductor device according to claim 1, wherein the anchor includes a dummy wire bonded to between a substrate mounted with the plurality of semiconductor chips and the first semiconductor chip.

3. The semiconductor device according to claim 1, wherein the anchor includes a projection provided on the first semiconductor chip.

4. The semiconductor device according to claim 1, wherein the anchor is disposed at such an edge of the first semiconductor chip as to enable an edge of the bonding resin with an interface being formed between the bonding resin and the sealing resin to be seized outside an area formed with an electronic circuit on the surface of the first semiconductor chip.

5. The semiconductor device according to claim 1, wherein the anchor is disposed at a portion, of the first semiconductor chip, to which a wire for electrically connecting the substrate mounted with the plurality of semiconductor chips to the first semiconductor chip is not bonded.

6. A manufacturing method of a semiconductor device, comprising:
a step of bonding a plurality of semiconductor chips mutually via a bonding resin;
a step of sealing the plurality of semiconductor chips by a sealing resin; and
a step of disposing an anchor to seize the bonding resin in a first semiconductor chip included by the plurality of semiconductor chips.

7. The manufacturing method of the semiconductor device according to claim 6, wherein the anchor includes a dummy wire bonded to between a substrate mounted with the plurality of semiconductor chips and the first semiconductor chip.

8. The manufacturing method of the semiconductor device according to claim 6, wherein the anchor includes a projection provided on the first semiconductor chip.

9. The manufacturing method of the semiconductor device according to claim 6, wherein the anchor is disposed at such an edge of the first semiconductor chip as to enable an edge of the bonding resin with an interface being formed between the bonding resin and the sealing resin to be seized outside an area formed with an electronic circuit on the surface of the first semiconductor chip.

10. The manufacturing method of the semiconductor device according to claim 6, wherein the anchor is disposed at a portion, of the first semiconductor chip, to which a wire for electrically connecting the substrate mounted with the plurality of semiconductor chips to the first semiconductor chip is not bonded.
